(19) United States
(12) Patent Application Publication
(10) Pub. No.: US 2015/0263220 A1
(43) Pub. Date: Sep. 17, 2015

(54) SEMICONDUCTOR LIGHT-EMITTING ELEMENT AND METHOD FOR MANUFACTURING THE SAME

(71) Applicant: STANLEY ELECTRIC CO., LTD., Tokyo (JP)

(72) Inventor: Takayoshi YAMANE, Yokohama-shi (JP)

(73) Assignee: STANLEY ELECTRIC CO., LTD., Tokyo (JP)

(21) Appl. No.: 14/659,463

(22) Filed: Mar. 16, 2015

(30) Foreign Application Priority Data
Mar. 17, 2014 (JP) 2014-053661

(51) Int. Cl. H01L 33/00; H01L 33/32

(52) U.S. Cl. CPC H01L 33/0075; H01L 33/32

(57) ABSTRACT

A method for manufacturing a light-emitting element made of a GaN-based semiconductor with an MOCVD method includes the steps of: growing an n-type semiconductor layer; growing an active layer on the n-type semiconductor layer; and growing a p-type AlGaN-based semiconductor layer on the active layer while maintaining a concavo-convex surface with a depth of 1 to 5 nm.

### BACKGROUND OF THE INVENTION

1. Field of the Invention

The present invention relates to a semiconductor light-emitting element and a method for manufacturing the same. In particular, the present invention relates to a gallium nitride (GaN)-based semiconductor light-emitting element and a method for manufacturing the same.

2. Description of the Related Art

Light-emitting diodes (LEDs) employing a nitride semiconductor such as a GaN-based semiconductor are being utilized in various fields. In particular, some LEDs capable of withstanding use in an environment severer than that for a common LED are being demanded. More specifically, favorable emission characteristics of LEDs comparable to when operated at a room temperature are needed at the time of large current density driving or high-temperature driving. In other words, there is a demand for LEDs in which a droop phenomenon is hard to happen and which have excellent temperature characteristics, the called droop phenomenon is a phenomenon such that an emission intensity is lowered at the time of high current density driving.

One of factors for causing the droop phenomenon in the GaN-based LED is poor hole injection into an active layer. Mg is being widely used as a typical dopant to be a hole source. Regarding Mg, however, if H (hydrogen) is present in a crystal as an impurity, the H inactivates an Mg acceptor, thereby preventing the function of holes.

It has been confirmed that the activation rate of Mg is improved by subjecting such an Mg-doped GaN semiconductor to electron beam irradiation (H. Amano et al., JJAP 28, L2112 (1989)) or heat treatment (S. Nakamura et al., JJAP 31, 1258 (1992)). An Mg-doped nitride-based semiconductor layer is generally subjected to heat treatment for causing the detachment of hydrogen in a nitrogen gas atmosphere, or the like, after the growth thereof.

Under these circumstances, attempts to reduce a hydrogen concentration in a crystal in an MOCVD (Metal Organic Chemical Vapor Deposition) method have been made with various approaches. More specifically, there has been known that the resistance or contact resistance of a p-type semiconductor layer is reduced by focusing attention on a carrier gas during the growth thereof. For example, there has been described hat nitrogen is used as a main carrier gas during the formation of a semiconductor layer to be a p-type layer and during a temperature-lowering process after such formation so as to prevent the formation of a composite of Mg and hydrogen, thereby facilitate the entering of Mg into a Ga site, and thus activate Mg without heat treatment in Japanese Patent Application Laid-Open No. Hei. 10-135575. Also, there has been described a method for obtaining a p-type conductive layer by replacing an atmosphere gas by an inert gas other than an H₂ gas and an NH₃ gas in a temperature-lowering process after the completion of the growth thereof in Japanese Patent Application Laid-Open No. Hei. 8-125222. Also, there has been described that a hole concentration can be increased by introducing a halogen element such as fluorine or chlorine, for example, into a p-type layer in Japanese Patent Application Laid-Open No. 2009-43970. Also, there has been described a method including the steps of: growing a first Mg-doped GaN-based semiconductor film in a carrier gas atmosphere containing hydrogen at a higher rate than nitrogen; interrupting, after such a growing step, the supply of a group III source gas; and growing an Mg-doped second GaN-based semiconductor film in a carrier gas atmosphere containing nitrogen at a higher rate than hydrogen, wherein an effective acceptor concentration can be increased as a result of obtaining a higher concentration of Mg and a lower concentration of hydrogen in Japanese Patent Application Laid-Open No. 2010-45396.

### SUMMARY OF THE INVENTION

The present invention has been made in view of the aforementioned respects. It is an object of the present invention to provide a high-performance semiconductor light-emitting element capable of: suppressing the mixing-in of hydrogen into a p-type AlGaN layer; improving a hole injection efficiency into an active layer; having a high emission efficiency; and reducing a reduction (droop) in an emission intensity thereof even at the time of high current driving, and a method for manufacturing the same.

A manufacturing method of the present invention is a method for manufacturing a light-emitting element with an MOCVD method, comprising the steps of:

growing an n-type semiconductor layer;

growing an active layer on the n-type semiconductor layer; and

growing a p-type AlGaN-based semiconductor layer on the active layer while maintaining a concavo-convex surface with a depth of 1 to 5 nm.

A light-emitting element of the present invention is a light-emitting element made of a GaN-based semiconductor, comprising:

an n-type semiconductor layer;

an active layer formed on the n-type semiconductor layer;

a p-type AlGaN-based semiconductor layer formed on the active layer; and

a p-type GaN semiconductor layer formed on the p-type AlGaN-based semiconductor layer, wherein

a concavo-convex structure is formed on an interface between the p-type AlGaN-based semiconductor and the p-type GaN semiconductor layer;

a concentration of hydrogen (H) mixed into the p-type AlGaN-based semiconductor layer is lower than or equal to a concentration of hydrogen (H) mixed into the p-type GaN semiconductor layer.

### BRIEF DESCRIPTION OF THE DRAWINGS

The aforementioned aspects and other features of the present invention are explained in the following description, taken in connection with the accompanying drawing figures wherein:

FIG. 1 is a cross-sectional view schematically illustrating a configuration of a semiconductor structure layer of an LED according to a first embodiment;

FIG. 2 shows a TEM image of a cross section of the semiconductor structure layer according to the present embodiment;

FIG. 3 shows a TEM image of a cross section of a semiconductor structure layer according to a comparative example;

FIG. 4 is a graph showing SIMS measurement results before annealing the semiconductor structure layer according to the present embodiment;

FIG. 5 is a graph showing SIMS measurement results after annealing the semiconductor structure layer according to the present embodiment;

FIG. 6 shows an SIMS profile of a growth layer when a p-GaN layer was grown with Mg being doped;

FIG. 7 shows an SIMS profile of a growth layer when a p-AlGaN layer was grown with Mg being doped;

FIG. 8 shows an SIMS profile of the semiconductor structure layer according to the comparative example after annealing; and

FIG. 9 is a graph comparing a relationship between a drive current value and an emission intensity in an LED element of the present embodiment with that in the comparative example.

### DETAILED DESCRIPTION OF THE INVENTION

Although preferred embodiments of the present invention will be described below, these embodiments may be appropriately modified and combined one another. Also, in the following description and accompanying drawings, substantially the same or equivalent parts will be denoted by the same reference numerals.

### First Embodiment

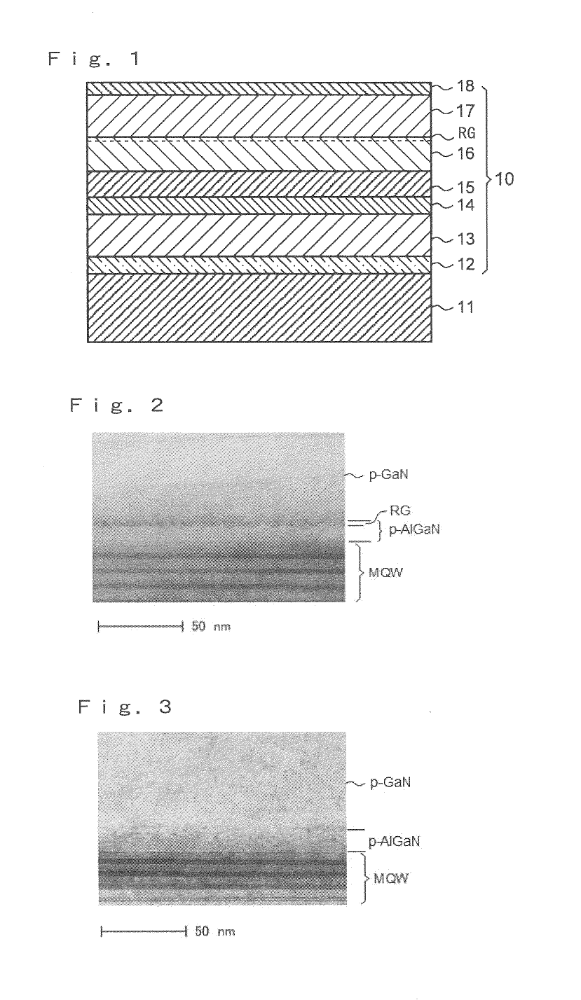

FIG. 1 is a cross-sectional view schematically illustrating a configuration of a semiconductor structure layer 10 of an LED according to the first embodiment of the present invention. As shown in FIG. 1, a GaN buffer layer 12, an n-GaN layer 13, a super lattice structure (SLS) layer 14, a multiple quantum well (MQW) active layer (MQW-ACT) 15, a p-AlGaN layer 16, a p-GaN layer 17, and a GaN contact layer 18 are sequentially formed in this order on a substrate 11.

### [Formation of Semiconductor Structure Layer]

Steps of manufacturing the semiconductor structure layer 10 will now be described below in detail. A sapphire single crystal substrate with a growth plane being a C-plane was used as a substrate for growing the semiconductor structure layer 10. The semiconductor structure layer 10 was grown on the growth substrate 11 with the MOCVD method.

Trimethylgallium (TMG), trimethylaluminum (TMA), and trimethylindium (TMI) were used as group III organometallic raw materials. Ammonia (NH₃) was used as a group V hydride raw material. Disilane (Si₂H₆) was used as an n-type dopant and biscyclopentadienyl magnesium (CP₂Mg) was used as a p-type dopant. Hydrogen (H₂) and nitrogen (N₂) were used as carrier gases. Crystal growth was performed in a normal pressure atmosphere.

First, the sapphire substrate was annealed for ten minutes at 1000° C. in a mixed carrier gas of H₂ and N₂. Next, the substrate temperature was adjusted at 500° C. and the low-temperature growth GaN buffer layer (hereinafter simply referred to as a buffer layer) 12 with a layer thickness of 30 nm (nanometers) was grown on the sapphire substrate 11 with the use of TMG and NH₃.

Next, hydrogen (H₂) was used as a carrier gas and the substrate temperature was raised to 1000° C. in an NH₃ atmosphere. After the GaN buffer layer 12 was annealed for seven minutes, TMG and Si₂H₆ were supplied so as to grow the Si-doped n-GaN layer 13 with a layer thickness of 5 μm on the GaN buffer layer 12.

Next, the substrate temperature was decreased to 750° C. in a mixed atmosphere of NH₃, N₂, and H₂. After the substrate was stabled at the constant temperature, the supply of H₂ was stopped while supplying TMG, TMI, and NH₃ so as to grow the super lattice structure (SLS) layer 14.

After the growth of the super lattice structure layer 14, a step of forming an InGaN well layer by means of the supply of TMI and TMG during the supply of NH₃ and then forming a GaN burrier layer while stopping the supply of TMI was repeated so as to grow the undoped InGaN-based semiconductor MQW active layer (light-emitting layer) 15. More specifically, the composition and layer thickness of the well layer were determined so that the emission wavelength thereof (the bandgap of the MQW) is 450 nm. Note that the burrier layer may be another GaN-based semiconductor layer such as an InGaN layer, for example. Moreover, the super lattice structure layer 14 may not necessarily be provided and the active layer 15 may be provided on the n-GaN layer 13. Furthermore, the active layer 15 may be a single quantum well (SQW) or a single layer (so-called a bulk) without being limited to the MQW active layer.

Next, the substrate temperature was raised to 1000° C. in a mixed atmosphere of NH₃, N₂, and H₂. After the substrate was stabled at the constant temperature, the Mg-doped p-AlₓGa₁₋ₓN layer 16 was grown on the active layer 15.

The crystal growth of the Mg-doped p-AlₓGa₁₋ₓN layer 16 was performed so that the growth surface thereof kept having a concavo-convex structure from the start to the completion of the growth by employing a carrier gas mixed so as to achieve an F value (i.e., a rate of hydrogen in the carrier gas), to be described later in detail, of 0.23 and supplying TMG, TMA, and CP₂Mg as well as NH₃ in an amount for achieving a V/III ratio of 70000. In other words, the crystal growth was performed under such conditions that the concavo-convex surface was being maintained from the very early stage of the growth.

Although the depth of the concavo-convex structure RG was formed so as to be 2 to 3 nm (nanometers), it is preferable that the concavo-convex structure RG be formed in a depth range of 1 nm or more and 5 nm or less. Moreover, it is preferable that the crystal be grown so that facets thereof are developed.

The layer thickness of the Mg-doped p-AlₓGa₁₋ₓN layer 16 was 20 nm and the Al composition (x) of the layer 16 was 21% (x=0.21). The Mg concentration of the layer 16 was 1.5×10²⁰ atoms/cm³. The AlₓGa₁₋ₓN layer 16 (0<x) has a larger bandgap than the burrier layer of the MQW active layer 15 and functions also as an electron blocking layer.

Note that, immediately after the growth of the layer immediately under the p-AlₓGa₁₋ₓN layer 16 (i.e., the growth layer immediately before the growth of the p-AlₓGa₁₋ₓN layer 16; the active layer 15 in this embodiment), there is performed a trigger for causing the crystal growth of the p-AlₓGa₁₋ₓN layer 16 having the concavo-convex structure to the outermost surface of such a layer immediately thereunder (the growth-completed surface of the active layer 15), whereby the Mg-doped p-AlₓGa₁₋ₓN layer 16 having the concavo-convex surface can be grown. More specifically, the p-AlₓGa₁₋ₓN layer 16 having the concavo-convex surface can be grown by forming the outermost surface of such a layer immediately thereunder as a rough surface having the concavo-convex structure in a range of 1 nm or more and 5 nm or less.

After the growth of the Mg-doped p-AlₓGa₁₋ₓN layer 16, the supply of TMG and TMA was stopped and the substrate temperature was raised to 1100° C. After the substrate temperature was stabled at 1100° C., NH₃, TMG, and CP₂Mg were supplied so as to grow the p-GaN layer 17 with a layer thickness of 97 nm as a second semiconductor layer (p-type) on the p-AlₓGa₁₋ₓN layer 16 (first semiconductor layer). Thereafter, the supply amount of CP₂Mg was increased so as to grow the GaN contact layer 18, functioning as a p-contact layer, with a layer thickness of 3 nm.

Thus, after the growth of the semiconductor structure layer 10, electrodes connected to the p-contact layer 18 and the n-GaN layer 13 were provided, thereby producing an LED element. The characteristic evaluation thereof was then performed.

### [Analysis Results of Semiconductor Structure Layer]

Samples of the semiconductor structure layer 10 formed according to the above-described embodiment were evaluated. Also, a semiconductor structure layer provided with a flat Mg-doped p-AlₓGa₁₋ₓN layer without any concavo-convex structure in place of the Mg-doped p-AlₓGa₁₋ₓN layer 16 according to the present embodiment was grown and evaluated as a comparative example for the present embodiment.

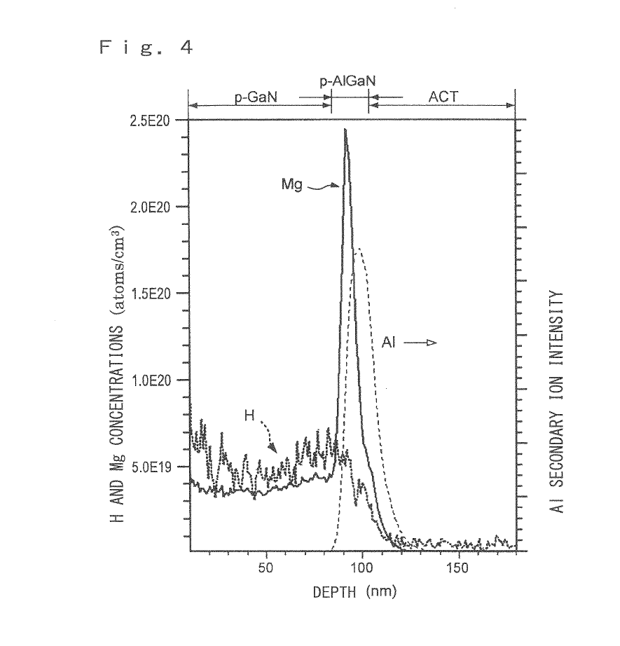

FIG. 2 shows a TEM (Transmission Electron Microscope) bright-field image of a cross section of the semiconductor structure layer 10 according to the present embodiment. FIG. 3 similarly shows a TEM image of a cross section of the semiconductor structure layer according to the comparative example for the present embodiment. The TEM image of the semiconductor structure layer 10 according to the present embodiment shows a part of the MQW active layer 15, the p-AlₓGa₁₋ₓN layer 16, the concavo-convex interface layer RG, and a part of the p-GaN layer 17. It can be confirmed that the concavo-convex interface layer RG is present like a shadow at an interface between the p-AlₓGa₁₋ₓN layer 16 and the p-GaN layer 17. Note that the concavo-convex interface layer RG is a part of the p-AlₓGa₁₋ₓN layer 16 (the surface layer of the p-AlₓGa₁₋ₓN layer 16). As described above, the p-AlₓGa₁₋ₓN layer 16 was grown so as to keep having a growth surface with concavo-convex from the very early stage of the growth to the completion of the growth.

On the other hand, although the TEM image of the comparative example shows a part of an MQW active layer, the p-AlₓGa₁₋ₓN layer, and a p-GaN layer as shown in FIG. 3, it can be seen that the semiconductor structure layer according to the comparative example has no concavo-convex interface layer and therefore the p-AlₓGa₁₋ₓN layer has been grown evenly.

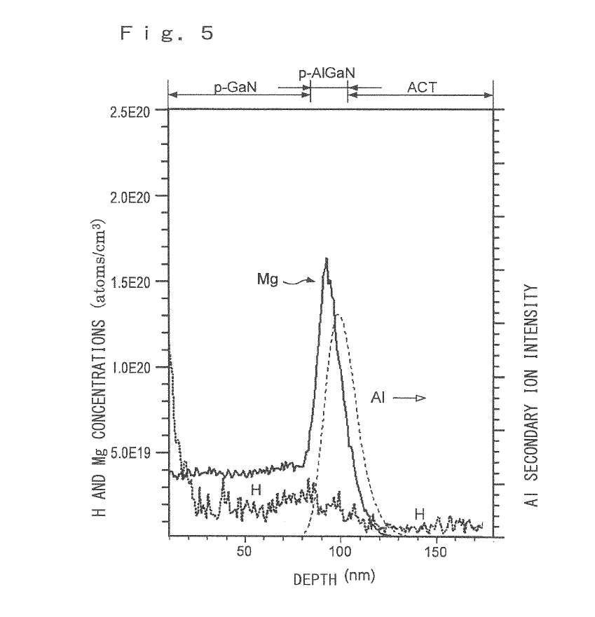

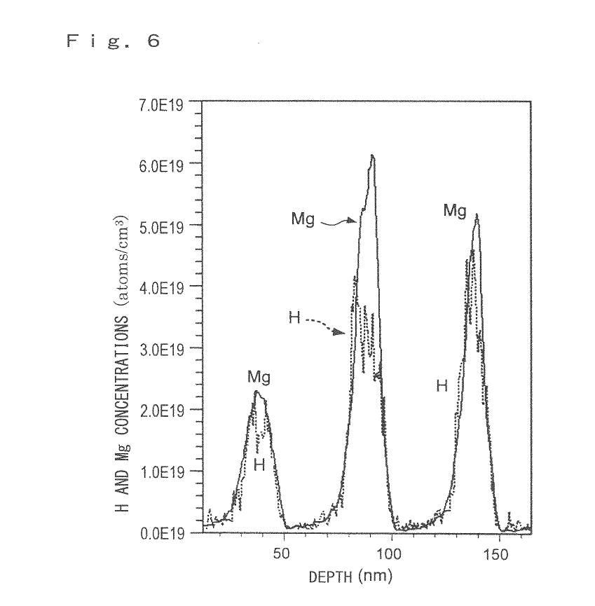

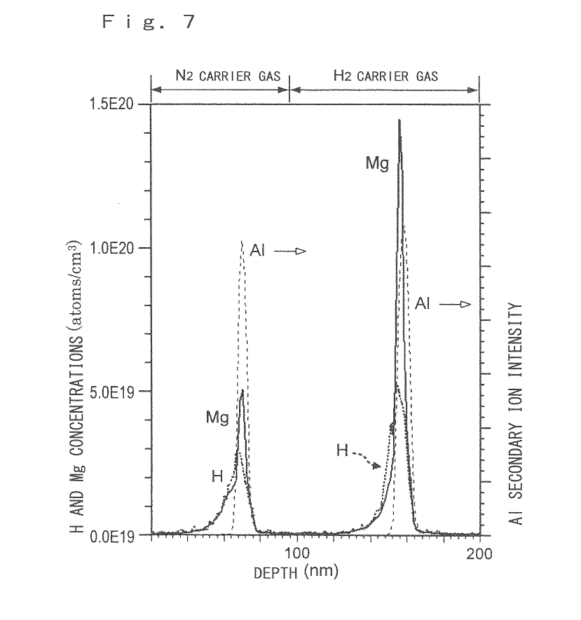

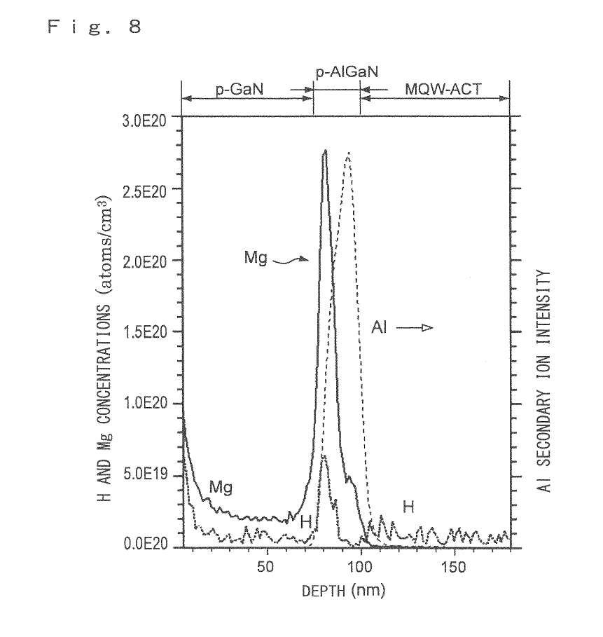

FIGS. 4 and 5 are graphs showing SIMS (Secondary Ion Mass Spectroscopy) measurement results before and after annealing the semiconductor structure layer 10 according to the present embodiment, respectively. First, the result of a preliminary verification experiment for verifying that hydrogen (H) is mixed into a growth layer will be described below with reference to FIGS. 6 and 7.

FIG. 6 shows an SIMS profile of the growth layer when a p-GaN layer was grown with Mg being doped. FIG. 7 shows an SIMS profile of the growth layer when a p-AlGaN layer was grown with Mg being doped. In FIGS. 6 and 7, a vertical axis on the left side represents hydrogen (H) and Mg concentrations (atoms/cm³). In FIG. 7, a vertical axis on the right side represents Al (aluminum) secondary ion intensities in order to clarify the position of the AlGaN layer (in other words, an extent of the Al secondary ion intensity curve represents the position of the AlGaN layer). A solid line represents Mg concentrations, a dotted line represents H concentrations, and a broken line (FIG. 7) represents Al secondary ion intensities. Note that mEn is exponent notation in the figures and 1.5E20, for example, represents 1.5×10²⁰.

As shown in FIG. 6, it can be seen that when the p-GaN layer is grown with Mg being doped, hydrogen (H) is mixed in at a high concentration in conjunction with the intake of Mg into the growth layer. FIG. 7 illustrates a case where the carrier gas is changed from nitrogen (N₂) to hydrogen (H₂) in the middle of the growth of the Mg-doped p-AlGaN layer. Regardless of whether the carrier gas is nitrogen or hydrogen, hydrogen (H) is mixed in at a high concentration in the growth of p-AlGaN in conjunction with the intake of Mg into the growth layer. The reason for this can be considered that even when the carrier gas is an inert gas such as nitrogen or a gas containing no hydrogen, hydrogen (H) generated by the decomposition of NH₃ (ammonia) employed as a source gas is mixed in.

In this manner, when a p-type semiconductor layer is grown in a light-emitting element (for example, an LED) made of a GaN-based semiconductor manufactured with the MOCVD method, a large amount of H is mixed into the crystal if Mg is used as a p-type dopant. The amount thereof is approximately at the same level as the amount of Mg and the behavior thereof acts in conjunction with the intake of Mg. This suggests that the intake of Mg into the crystal occurs in the form of Mg—H due to hydrogen (H) in a growth system. If such is the case, Mg as a hole source becomes inactivated, thereby inhibiting efficient hole injection into the active layer. Therefore, the droop phenomenon such that an output power is lowered at the time of a large current density operation or a high-temperature operation becomes prominent.

Referring back to FIG. 4, this figure shows an SIMS profile in a depth direction from the outermost surface. Upon the measurements, sputtering with Cs ions was performed from the top layer and obtained elements were analyzed. A vertical axis on the left side represents hydrogen (H) and Mg concentrations (atoms/cm³). A vertical axis on the right side represents Al secondary ion intensities (broken line) in order to clarify the position of the AlGaN layer. An upper part of FIG. 4 describes the layer structure.

FIG. 4 shows the SIMS profile of the semiconductor structure layer according to the present embodiment before annealing. Focusing attention on the Mg concentration in the crystal, Mg is doped at a high concentration of 2.5×10²⁰ atoms/cm³ in the p-AlGaN, whereas Mg is doped at 4.0×10¹⁹ atoms/cm³ in the p-GaN.

Next, focusing attention on the mixing-in of H, it can be seen that H is mixed into the GaN generally at about 5.0×10¹⁹ atoms/cm³. From the perspective of the quantitative relationship between Mg and H, approximately the same amounts of H and Mg are taken into the GaN. This coincides with the aforementioned preliminary experiment's result. In contrast, observing the mixing-in of H in the AlGaN, a slightly-greater amount of H is mixed in as compared to the background level. Such an amount, however, is approximately at a level same as or lower than the amount in the GaN. Moreover, from the perspective of the relationship with Mg, it can be seen that H exhibits a profile totally different from the behavior of Mg doped at a high concentration. This result can be considered to indicate that H was not mixed into the crystal or H was efficiently detached from the crystal in the AlGaN due to the development of growth in the presence of the concavo-convex structure on the surface thereof.

FIG. 5 shows the SIMS profile of the semiconductor structure layer according to the present embodiment after annealing. Observing the relationship of H with Mg in the p-GaN layer and the p-AlGaN layer, it can be seen that the concentration of H has been decreased to about one-half of that before annealing. Therefore, it can be seen that despite of Mg doping at a high concentration of the 20th power level in the AlGaN layer, H in the layer is almost kept to the background level mixed amount. The concentration of hydrogen (H) mixed into the p-type AlGaN layer is at least equal to or lower than the concentration of hydrogen (H) mixed into the p-type GaN layer.

FIG. 8 shows an SIMS profile of the semiconductor structure layer according to the comparative example after annealing. As described above, in the semiconductor structure layer according to the comparative example, crystal growth was performed in such a manner that the growth of the Mg-doped p-AlₓGa₁₋ₓN layer proceeds without having the concavo-convex surface. Focusing attention on the profile of H, the concentration of H fluctuates generally at the background level in the p-GaN layer since it is after annealing, but H in the p-AlGaN layer is mixed in at an extremely high concentration as compared to that in the p-GaN layer. More specifically, it can be seen that the concentration of H in the p-AlGaN layer is high as much as 7.0×10¹⁹ atoms/cm³. Moreover, from the perspective of the relationship with Mg, it can be seen that H is mixed in in conjunction with the highly-concentrated Mg in the p-AlGaN layer. This suggests that the intake of H into the crystal more often occurs in the form of Mg—H. Such an H concentration in the crystal has a strong correlation with the Mg concentration in the AlGaN. If Mg is doped at a higher concentration, a greater amount of H is mixed in correspondingly.

### [Characteristics of LED Elements]

An LED according to the above-described embodiment was fabricated so as to include the semiconductor structure layer 10 having the Mg-doped p-AlₓGa₁₋ₓN layer 16 grown as described above so that the mixing-in of hydrogen (H) was suppressed, and a p-electrode and an n-electrode formed thereon. Also, an LED was fabricated as a comparative example so as to include a semiconductor structure layer provided with the Mg-doped p-AlₓGa₁₋ₓN layer into which hydrogen (H) was mixed, and a p-electrode and an n-electrode formed thereon.

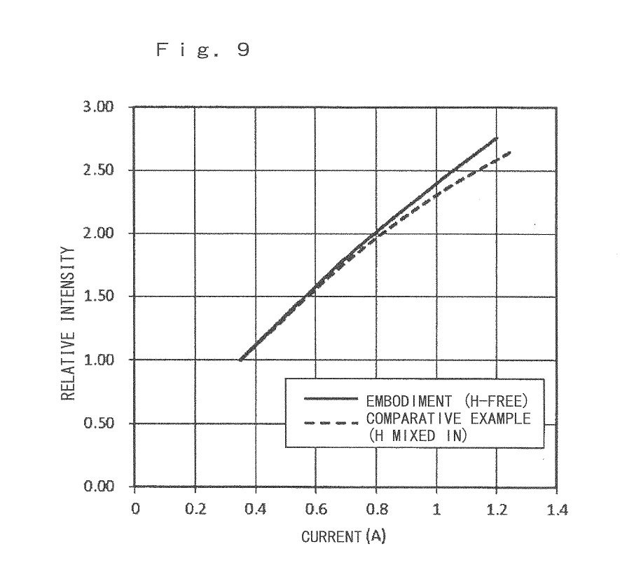

FIG. 9 is a graph comparing a relationship between a drive current value and an emission intensity in the LED element of the present embodiment with that in the comparative example. A solid line thereof represents characteristics in the case of the present embodiment having the Mg-doped p-AlₓGa₁₋ₓN layer in which the mixing-in of hydrogen (H) was suppressed. A broken line thereof represents characteristics in the case of the comparative example having the Mg-doped p-AlₓGa₁₋ₓN layer into which hydrogen (H) was mixed. Note that the graph is shown with relative emission intensities (vertical axis) for comparison.

As shown in FIG. 9, when the current value is about 0.4 A (ampere), the emission intensities of the LED elements of the present embodiment and the comparative example are approximately at the same level. In the LED of the comparative example, however, along with an increase in the current value, the relative emission intensity thereof starts to deviate from a proportional relationship. An increase in the emission intensity (slope efficiency, i.e., an increase in the emission intensity with respect to an increase in the current) starts to decrease when the current value is about 0.8 A, for example. Around 1.2 A, the rate of increase in the emission intensity is greatly decreased. This clearly indicates the droop phenomenon. In the LED of the present embodiment, on the other hand, droop in the emission intensity is less and the emission intensity thereof is increased even at the current value of 1.2 A while maintaining the proportional relationship with the drive current. While this experiment data shows the current value range of about 0.35 A to about 1.2 A, the LED element according to the present embodiment had better droop characteristics than the LED element according to the comparative example even in a larger current region. In other words, the provision of the p-AlₓGa₁₋ₓN layer according to the present embodiment in which the mixing-in of hydrogen (H) is suppressed enables the suppression of the droop phenomenon. In other words, it is possible to provide an LED element with a high emission efficiency even at the time of large current driving. Therefore, a semiconductor light-emitting element with less deterioration and high reliability can be provided.

Furthermore, temperature characteristics of the LED elements according to the present embodiment and the comparative example were evaluated. The LED element was placed on a Peltier element and luminance thereof was measured while stabilizing the temperature thereof at 25° C. and 70° C. A power roll-off ratio (hereinafter sometimes referred to simply as a roll-off ratio) expressed by the following formula was used as an evaluation index parameter.

Power roll-off ratio(%)=luminance at the operation temperature of 70° C./luminance at the operation temperature of 25° C.×100.

Whereas the roll-off ratio of the element in which the H impurity concentration in the p-AlGaN layer was 5.0×10¹⁹ atoms/cm³ was 92.3%, the roll-off ratio of the element in which the H impurity concentration was reduced to 2.5×10¹⁹ atoms/cm³ was 93.1%. Thus, superiority by 0.8% was confirmed. It can be considered that this result was obtained because an amount of active holes is increased due to the reduced H impurities in the p-AlGaN layer and electrons overflowed from the n-type semiconductor can be efficiently recombined with the holes in the active layer even at the time of high-temperature driving.

[p-AlGaN Layer Grown with Concavo-Convex Surface]

The p-AlGaN layer 16 according to the present embodiment functions also as an electron blocking layer (EBL). Thus, the Al composition of the p-AlGaN layer 16 is selected so that the p-AlGaN layer has a composition (bandgap) capable of fulfilling its function. The LED according to the present embodiment emits light in a range of 440 to 450 nm, for example, and the Al composition of the p-AlGaN layer 16 is in a range of about 5 to 300.

As described above, the p-AlGaN layer 16 was grown under such conditions that a concave-convex surface was maintained from the very early stage of the growth. It can be considered that planes (facets) different from the growth plane (C-plane) are developed in the concavo-convex portion. It can be considered that the main plane thereof is a {11-22}-plane (R-plane) oblique to the C-plane.

### [Mechanism for Suppressing Mixing-in of H by Means of Concavo-Convex Surface]

The presence of the concavo-convex surface indicates that crystal planes each having a plane direction different from that of the growth plane have been developed. If such different planes are present, atomic arrangement on the surface thereof is different, thereby changing the intake amount of H.

Meanwhile, since Mg comes into the group III site, Mg is replaced by Ga or Al in most cases. In +C-plane growth, the group III has one back bond upwardly (in a direction away from the crystal) and three back bonds downwardly (in a direction toward the crystal). When the growth proceeds along the C-axis, H in the Mg—H bond is exposed to a space more in the case of the concavo-convex surface where the space is spread both upwardly and laterally than in the case of the flat surface where the space is spread only upwardly. Thus, it can be considered that H in the concavo-convex surface is more easily detached as compared to the flat surface.

### [Method for Forming the Concavo-Convex Surface]

Timing at which the concavo-convex surface is formed is as follows: (i) immediately after the growth of the active layer (or the crystal layer immediately before the growth of the p-AlGaN layer) and during a period transitioning to the growth conditions of the p-AlGaN layer; or (ii) immediately after having been transitioned to the growth conditions of the p-AlGaN layer and at the beginning of the growth of the p-AlGaN layer.

The aforementioned (ii) will now be described below in detail.

(1) Control of Supply Ratio between Group V and Group III Raw Materials (V/III Ratio)

In the growth of GaN by means of the MOCVD method, the V/III ratio is typically about 10000. In general, for the growth of AlN, a low V/III ratio, specifically about 5 to 100, is employed. For AlGaN with an Al composition (x) of 5 to 30%, a V/III ratio in a range of about 7000 to 9500 is typically employed. According to the present invention, however, a V/III ratio in a range of 20000 to 150000, which is the condition not normally employed, is used. From the perspective of the depth and size of the concavo-convex structure, the V/Ill ratio is preferably in a range of 50000 to 150000 and more preferably in a range of 50000 to 80000. By setting the V/III ratio extremely high in this manner, the p-AlGaN layer can be grown while maintaining the concavo-convex surface.

### (2) Crystal Growth Temperature

While AlGaN is a mixed crystal of GaN and AlN, the optimal growth temperature of GaN is different from that of AlN. A typical growth temperature is considered to be about 1000° C. for GaN and 2000° C. or higher for AlN. AlGaN which is a mixed crystal of GaN and AlN has an optimal growth temperature variable depending on its composition. If the temperature is low, the concavo-convex structure is more likely to be formed. If the temperature is high, flattening is more likely to occur. For an AlGaN crystal with an Al composition in a range of 5 to 30%, a standard for the growth temperature is about 1050 to 1250° C. In the above-described embodiment, however, AlGaN is grown at a relatively low temperature of 1000° C. Note that the range of the growth temperature is preferably 900° C. to 1250° C.

### (3) Rate of Hydrogen in Carrier Gas

The F value i.e., rate of hydrogen in a carrier gas is expressed by the following formula. Here, P_{H2} represents the partial pressure of a hydrogen gas in a growth furnace and P_{IG} represents the partial pressure of an inert gas in the growth furnace. Specifically, N₂ or a rare gas such as Ar or He is used as an inert gas.

F=P_{H2}/P_{H2}+P_{IG})

If the F value is small, the concavo-convex surface is more likely to be formed. If the F value approaches zero (inert gas only), however, the obtained concavo-convex surface have intensely defective crystallinity. In other words, it is preferable that the growth be performed in a reducing atmosphere. If the F value is large, on the other hand, flattening is developed. In the above-described embodiment, the F value was set at 0.23.

As described above, the present invention utilizes uneven growth having an effect of suppressing the mixing-in of H. The above-described various conditions such as the V/III ratio, the growth temperature, and the rate of hydrogen in the carrier gas can be determined as conditions for concavo-convex surface growth having a high suppressive effect on the mixing-in of H, i.e., growth conditions for performing growth while maintaining fine crystal planes (facets) each with a plane direction different from that of the growth plane on the surface of AlGaN. In other words, optimal concavo-convex surface growth can be achieved by appropriately combining the above-described various conditions one another.

Although the aforementioned embodiment has been described on the basis of the case where an organometallicmaterial containing Mg (CP₂Mg) is used as a p-type dopant for the AlGaN layer, the mixing-in of H can be suppressed also when another dopant is used according to the mechanism of the mixing-in of H.

Moreover, although the case where the p-AlGaN layer is grown on the active layer has been described, the present invention can be applied also to a case where the p-AlGaN layer is grown after forming a GaN-based semiconductor layer such as GaN, for example, on the active layer. In such a case, the bandgap of the GaN-based semiconductor layer is smaller than the bandgap of the p-AlGaN layer.

As described above in detail, by suppressing the mixing-in of hydrogen (H) into the p-AlₓGa₁₋ₓN layer, the inactivation of the dopant (Mg) as a hole source can be suppressed according to the present invention. As a result, holes can be efficiently injected into the active layer, thereby improving the droop phenomenon such that an output power is lowered at the time of a large current density operation or a high-temperature operation. Therefore, a high-performance semiconductor light-emitting element with a high emission efficiency in which a reduction (droop) in the emission intensity thereof is reduced even at the time of high current driving and a method for manufacturing the same can be provided. Moreover, a semiconductor light-emitting element with less deterioration and high reliability can be provided.

It is understood that the foregoing description and accompanying drawings set forth the preferred embodiments of the present invention at the present time. Various modifications, additions and alternative designs will, of course, become apparent to those skilled in the art in light of the foregoing teachings without departing from the spirit and scope of the disclosed invention. Thus, it should be appreciated that the present invention is not limited to the disclosed embodiments but may be practiced within the full scope of the appended claims.

This application is based upon and claims the benefit of priority from the prior Japanese Patent Application No. 2014-053661 filed on Mar. 17, 2014, the entire contents of which are incorporated herein by reference.

What is claimed is:

1. A method for manufacturing a light-emitting element made of a GaN-based semiconductor with an MOCVD method, comprising the steps of:
growing an n-type semiconductor layer;
growing an active layer on the n-type semiconductor layer; and
growing a p-type AlGaN-based semiconductor layer on the active layer while maintaining a concavo-convex surface with a depth of 1 to 5 nm.

2. The manufacturing method according to claim 1, wherein the p-type AlGaN-based semiconductor layer is grown with Mg being doped.

3. The manufacturing method according to claim 1, wherein the step of growing the active layer grows the active layer so that a growth-completed surface of the active layer has a concavo-convex structure in a range of 1 nm or more and 5 nm or less.

4. The manufacturing method according to claim 1, wherein the step of growing the p-type AlGaN-based semiconductor layer comprises a step of growing a GaN-based semiconductor layer having a bandgap smaller than that of the p-type AlGaN-based semiconductor layer on the active layer, and the p-type AlGaN-based semiconductor layer is grown on the GaN-based semiconductor layer while maintaining the concavo-convex surface.

5. The manufacturing method according to claim 1, wherein the p-type AlGaN-based semiconductor layer employs a gas containing no hydrogen (H) as a carrier gas and is grown with NH₃ (ammonia) as a source gas.

6. A light-emitting element made of a GaN-based semiconductor, comprising:
an n-type semiconductor layer;
an active layer formed on the n-type semiconductor layer;
a p-type AlGaN-based semiconductor layer formed on the active layer; and
a p-type GaN semiconductor layer formed on the p-type AlGaN-based semiconductor layer, wherein
a concavo-convex structure is formed on an interface between the p-type AlGaN-based semiconductor and the p-type GaN semiconductor layer;
a concentration of hydrogen (H) mixed into the p-type AlGaN-based semiconductor layer is lower than or equal to a concentration of hydrogen (H) mixed into the p-type GaN semiconductor layer.
